(19) United States
(12) Patent Application Publication
(10) Pub. No.: US 2023/0119356 A1
(43) Pub. Date: Apr. 20, 2023

(54) SEMICONDUCTOR LASER ELEMENT

(71) Applicant: Panasonic Holdings Corporation, Osaka (JP)

(72) Inventors: Takahiro NIBU, Osaka (JP); Masao KAWAGUCHI, Kyoto (JP); Hiroyuki HAGINO, Osaka (JP)

(21) Appl. No.: 17/909,681

(22) PCT Filed: Mar. 17, 2021
(86) PCT No.: PCT/JP2021/010942

§ 371 Date: Sep. 6, 2022

(30) Foreign Application Priority Data
Mar. 19, 2020 (JP) 2020-049780

(51) Int. Cl. H01S 5/34; H01S 5/343; H01S 5/22

(52) U.S. Cl. CPC H01S 5/3425; H01S 5/34333; H01S 5/22

(57) ABSTRACT

A semiconductor laser element includes a ridge, and includes: a p-type first clad layer; and a p-type second clad layer arranged on the p-type first clad layer, the p-type first clad layer has a superlattice structure of an AlₓGa₁₋ₓN layer and an Al_{y}Ga_{1-y}N layer (0≤x≤y≤1), the p-type second clad layer includes Al_{z}Ga_{1-z}N (0≤z≤y), the p-type first clad layer includes: a flat portion on which the p-type second clad layer is not arranged; and a protruding portion which protrudes upward from the flat portion and on which the p-type second clad layer is arranged, and the height of the protruding portion protruding from the flat portion is less than the thickness of the p-type first clad layer in the flat portion.

### CROSS-REFERENCE OF RELATED APPLICATIONS

This application is the U.S. National Phase under 35 U.S.C. § 371 of International Patent Application No. PCT/JP2021/010942, filed on Mar. 17, 2021, which in turn claims the benefit of Japanese Patent Application No. 2020-049780, filed on Mar. 19, 2020, the entire disclosures of which Applications are incorporated by reference herein.

### TECHNICAL FIELD

The present disclosure relates to semiconductor laser elements which include ridges.

The present application is a patent application to which Article 17 of Industrial Technology Enhancement Act applies based on research commissioned by New Energy and Industrial Technology Development Organization in 2016 “High-brightness and High-efficient Next Generation Laser Technology Development/New Light Source and Element Technology Development for Next-next-generation Processing/Development of GaN-based High-power, High-beam Quality Semiconductor Lasers for High-efficiency Processing”.

### BACKGROUND ART

Conventionally, semiconductor laser elements which include ridges are used. A ridge is formed, for example, by etching a semiconductor multilayer. As an example of a semiconductor laser element which includes an etching stop layer for stopping etching in a desired position, a semiconductor laser element disclosed in Patent Literature (PTL) 1 is present.

The semiconductor laser element disclosed in PTL 1 is a nitride semiconductor laser element which includes a clad layer and an insulating layer sequentially stacked on an active layer and also includes a ridge. The clad layer includes a first clad layer and a second clad layer and an etching stop layer arranged between these layers. Here, a difference between the refractive index of the etching stop layer and the refractive index of the insulating layer at the wavelength of laser light emitted from the active layer is greater than or equal to 0 and less than or equal to 0.4.

In order to obtain stable output characteristics in the semiconductor laser element in which the etching stop layer is arranged in the clad layer and the ridge is provided as described above, it is necessary to confine light not only in the formation region of a convex portion forming the ridge but also in a non-formation region where no convex portion is formed. Examples of the output characteristics in the semiconductor laser element here include a kink level (a current level at which the output characteristics of laser light with respect to current change rapidly), the spread angle of the laser light in a horizontal direction, and the like. In the semiconductor laser element disclosed in PTL 1, the difference between the refractive index of the etching stop layer and the refractive index of the insulating layer is less than or equal to 0.4. In this way, light confinement in the etching stop layer is compensated for by the insulating layer, and thus an attempt to achieve light confinement is made not only in the formation region of the convex portion but also in the non-formation region.

### CITATION LIST

### Patent Literature

[PTL 1] Japanese Unexamined Patent Application Publication No. 2006-108139

### SUMMARY OF INVENTION

### Technical Problem

In the semiconductor laser element disclosed in PTL 1, a selectivity ratio (that is, a ratio of the etching rate of GaN to the etching rate of AlGaN) which is a difference between the etching rate of an AlGaN layer used as the etching stop layer and the etching rate of a GaN layer is utilized to stop the etching. In the AlGaN layer, a difference in the etching rate is caused by a difference in the concentration of Al, and thus AlGaN of a high Al composition ratio is generally used for the etching stop layer. When the AlGaN layer of a high Al composition ratio is used as the etching stop layer, the selectivity ratio is high, and thus the etching is stopped in the etching stop layer. However, the AlGaN layer of a high Al composition ratio has high electrical resistance to cause an increase in the resistance of the semiconductor laser element. On the other hand, when AlGaN of a low Al composition ratio is used for the etching stop layer, the selectivity ratio is low, and thus the etching is not sufficiently stopped.

In view of the problem described above, an object of the present disclosure is to provide a semiconductor laser element which reduces an increase in resistance and can stop etching in a desired position.

### Solution to Problem

In order to solve the problem described above, a semiconductor laser element according to an aspect of the present disclosure is a semiconductor laser element that includes a ridge, the semiconductor laser element includes: a p-type first clad layer; and a p-type second clad layer arranged on the p-type first clad layer, the p-type first clad layer has a superlattice structure in which each of one or more AlₓGa₁₋ₓN layers and each of one or more Al_{y}Ga_{1-y}N layers are alternately stacked, where 0≤x≤y≤1, the p-type second clad layer includes Al_{z}Ga_{1-z}N, where 0≤z≤y, the p-type first clad layer includes: a flat portion on which the p-type second clad layer is not arranged; and a protruding portion which protrudes upward from the flat portion and on which the p-type second clad layer is arranged, the ridge includes the protruding portion and the p-type second clad layer arranged on the protruding portion, and a height of the protruding portion protruding from the flat portion is less than a thickness of the p-type first clad layer in the flat portion.

### Advantageous Effects of Invention

It is possible to provide a semiconductor laser element which reduces an increase in resistance and can stop etching in a desired position.

### BRIEF DESCRIPTION OF DRAWINGS

FIG. 1 is a schematic cross-sectional view showing an overall configuration of a semiconductor laser element according to Embodiment 1.

FIG. 2 is a schematic cross-sectional view showing a semiconductor stacking step in a method of manufacturing the semiconductor laser element according to Embodiment 1.

FIG. 3 is a schematic cross-sectional view showing a mask forming step in the method of manufacturing the semiconductor laser element according to Embodiment 1.

FIG. 4 is a schematic cross-sectional view showing a first etching step in the method of manufacturing the semiconductor laser element according to Embodiment 1.

FIG. 5 is a schematic cross-sectional view showing a second etching step in the method of manufacturing the semiconductor laser element according to Embodiment 1.

FIG. 6 is a schematic cross-sectional view showing an insulating layer forming step in the method of manufacturing the semiconductor laser element according to Embodiment 1.

FIG. 7A is a schematic cross-sectional view showing a first example of the shape of a ridge side surface and an etching surface formed by dry etching in a comparative example.

FIG. 7B is a schematic cross-sectional view showing a second example of the shape of the ridge side surface and the etching surface formed by the dry etching in the comparative example.

FIG. 8 is a cross-sectional view schematically showing an example of the shape of a ridge side surface and an etching surface formed by selectivity etching.

FIG. 9A is a schematic cross-sectional view showing a first example of the shape of a ridge side surface in Embodiment 1.

FIG. 9B is a schematic cross-sectional view showing a second example of the shape of the ridge side surface in Embodiment 1.

FIG. 10 is a graph showing the dependence of a selectivity ratio of GaN to AlGaN on the concentration of Al in AlGaN.

FIG. 11 is a schematic view showing a piezoelectric field applied to a superlattice structure formed with a GaN layer and an AlGaN layer.

FIG. 12 is a graph showing a difference in selectivity ratio between the superlattice structure and bulk AlGaN.

FIG. 13 is a cross-sectional view showing an overall configuration of a semiconductor laser element according to Embodiment 2.

### DESCRIPTION OF EMBODIMENTS

Embodiments of the present disclosure will be described below with reference to drawings. All the embodiments disclosed below are illustrative and not intended to restrict semiconductor laser elements according to the present disclosure. Hence, values, shapes, materials, constituent elements, the arrangements, positions, and connection forms of the constituent elements, and the like which are shown in the embodiments below are examples, and are not intended to limit the present disclosure.

The drawings each are schematic views, and are not exactly shown. Hence, in the drawings, scales and the like are not necessarily the same as each other. In the drawings, substantially the same configurations are identified with the same reference signs, and the repeated description thereof is omitted or simplified.

In the embodiments disclosed below, a detailed description beyond necessity may be omitted. For example, a detailed description of an already well known matter or a repeated description of substantially the same configuration may be omitted. This is intended for preventing the following description from being unnecessarily redundant and facilitating the understanding of a person skilled in the art.

In the following embodiments, the terms “upward” and “downward” do not indicate an upward direction (vertically upward) and a downward direction (vertically downward) in absolute spatial recognition. The terms “upward” and “downward” are applied not only to a case where two constituent elements are spaced with another constituent element present between the two constituent elements but also to a case where two constituent elements are arranged in contact with each other.

### Embodiment 1

A semiconductor laser element according to Embodiment 1 will be described.

### [1-1. Overall Configuration]

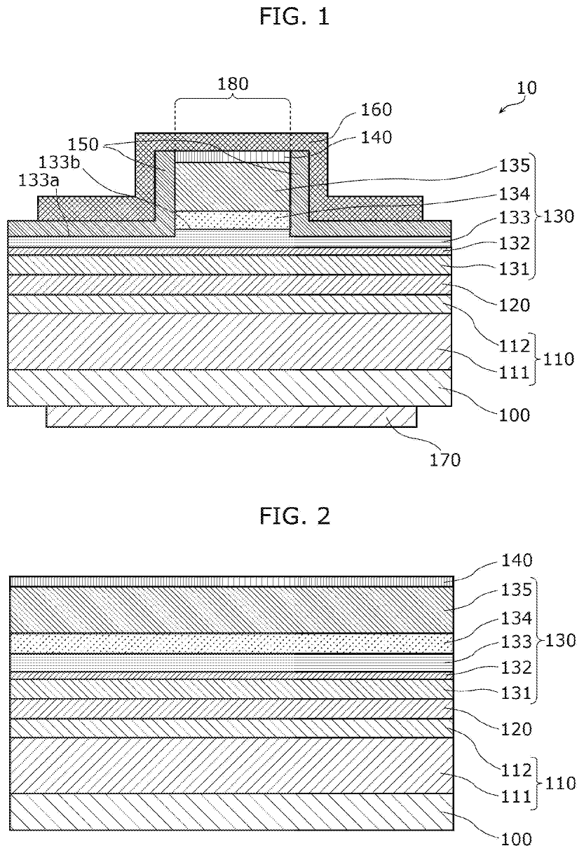

An overall configuration of the semiconductor laser element according to the present embodiment will first be described with reference to FIG. 1. FIG. 1 is a schematic cross-sectional view showing the overall configuration of semiconductor laser element 10 according to the present embodiment. FIG. 1 shows a cross section perpendicular to the longitudinal direction (that is, the direction of resonance of laser light) of ridge 180 included in semiconductor laser element 10. Semiconductor laser element 10 shown in FIG. 1 is a semiconductor laser element which includes ridge 180. Semiconductor laser element 10 mainly includes substrate 100, n-type semiconductor layer 110, active layer 120, p-type semiconductor layer 130, p-type contact layer 140, insulating layer 150, p electrode 160, and n electrode 170.

Substrate 100 is a plate-shaped member which serves as the base of semiconductor laser element 10. In the present embodiment, substrate 100 is an n-type GaN substrate, and is used as a substrate for epitaxially growing a group III-V nitride semiconductor. Substrate 100 is not limited to the n-type GaN substrate, and may be, for example, a sapphire substrate, a SiC substrate, or the like. Examples of a method for performing epitaxial growth on substrate 100 include metal-organic chemical vapor deposition (hereinafter, the MOCVD) and the like.

N-type semiconductor layer 110 is an example of a first conductive semiconductor layer arranged above substrate 100. In the present embodiment, the first conductive type is an n-type. N-type semiconductor layer 110 includes n-type clad layer 111 and n-side light guide layer 112. N-type semiconductor layer 110 may include a layer other than these layers. For example, n-type semiconductor layer 110 may include a buffer layer arranged between substrate 100 and n-type clad layer 111 or the like.

N-type clad layer 111 is an example of a first conductive clad layer arranged above substrate 100. In the present embodiment, n-type clad layer 111 includes, for example, Al_{0.05}Ga_{0.95}N which includes Si or the like as an n-type dopant. The thickness of n-type clad layer 111 is, for example, 3000 nm. N-type clad layer 111 may have, for example, a superlattice structure in which each of one or more n-type AlGaN layers and each of one or more n-type GaN layers are alternately stacked. In other words, n-type clad layer 111 may have a superlattice structure in which one or more multilayers are stacked, and in each of the one or more multilayers, an n-type AlGaN layer and an n-type GaN layer may be stacked.

N-side light guide layer 112 is an example of a first conductive side light guide layer arranged above the first conductive clad layer. In the present embodiment, n-side light guide layer 112 includes a GaN layer having a thickness of 250 nm and an In_{0.05}Ga_{0.95}N layer having a thickness of 100 nm which include Si or the like as an n-type dopant and are sequentially stacked from the side of n-type clad layer 111.

Active layer 120 is an example of a light emitting layer arranged above the first conductive semiconductor layer. In the present embodiment, active layer 120 has a single quantum well structure which includes InGaN. In other words, active layer 120 includes two barrier layers and a well layer arranged between the two barrier layers.

The In composition of the well layer is adjusted, and thus the wavelength of laser light emitted by semiconductor laser element 10 can be adjusted in a range of about 400 nm or more and 460 nm or less. In the present embodiment, the well layer is a GaN layer having a thickness of 8 nm, and the barrier layer is an In_{0.03}Ga_{0.97}N layer having a thickness of 15 nm. Active layer 120 may have a multiple quantum well structure in which a plurality of barrier layers and a plurality of well layers are alternately stacked. In other words, active layer 120 may have a multiple quantum well structure in which each of a plurality of well layers is arranged between two adjacent barrier layers of a plurality of barrier layers.

P-type semiconductor layer 130 is an example of a second conductive semiconductor layer arranged above active layer 120. The second conductive type is a conductive type different from the first conductive type, and is a p-type in the present embodiment. In the present embodiment, p-type semiconductor layer 130 includes p-side light guide layer 131, p-type overflow control layer (hereinafter, p-type OFS layer) 132, p-type first clad layer 133, p-type second clad layer 134, and p-type third clad layer 135.

P-side light guide layer 131 is an example of a second conductive side light guide layer arranged above active layer 120. In the present embodiment, p-side light guide layer 131 includes an In_{0.05}Ga_{0.95}N layer having a thickness of 70 nm and a GaN layer having a thickness of 15 nm which include Mg or the like as a p-type dopant and are sequentially stacked from the side of active layer 120.

P-type OFS layer 132 is a second conductive overflow control layer which is arranged above active layer 120 to reduce the leakage of carriers from active layer 120. In the present embodiment, p-type OFS layer 132 is a layer which is arranged above p-side light guide layer 131 to reduce the leakage of electrons from active layer 120, and is an Al_{0.4}Ga_{0.6}N layer which includes Mg or the like as a p-type dopant and has a thickness of 5 nm.

P-type first clad layer 133 is an example of a second conductive first clad layer arranged above active layer 120. In the present embodiment, p-type first clad layer 133 is arranged above p-type OFS layer 132. P-type first clad layer 133 has a superlattice structure in which each of one or more AlₓGa₁₋ₓN layers and each of one or more Al_{y}Ga_{1-y}N layers (0≤x≤y≤1) are alternately stacked. In other words, p-type first clad layer 133 has a superlattice structure in which one or more multilayers are stacked, and in each of the one or more multilayers, a p-type AlₓGa₁₋ₓN layer and a p-type Al_{y}Ga_{1-y}N layer (0≤x≤y≤1) are stacked. P-type first clad layer 133 may have a superlattice structure in which each of one or more AlₓGa₁₋ₓN layers and each of one or more Al_{y}Ga_{1-y}N layers (0≤x≤y≤0.5) are alternately stacked. P-type first clad layer 133 may have a superlattice structure in which each of one or more AlₓGa₁₋ₓN layers and each of one or more Al_{y}Ga_{1-y}N layers (0≤x≤y≤0.2) are alternately stacked. P-type first clad layer 133 may have a superlattice structure in which each of one or more AlₓGa₁₋ₓN layers and each of one or more Al_{y}Ga_{1-y}N layers (0≤x≤y≤0.1) are alternately stacked. In the present embodiment, p-type first clad layer 133 has a superlattice structure in which 10 GaN layers having a thickness of 3 nm and 10 Al₀₀₅Ga_{0.95}N layers having a thickness of 3 nm are alternately stacked, and includes Mg or the like as a p-type dopant.

P-type first clad layer 133 includes: flat portion 133a on which p-type second clad layer 134 is not arranged; and protruding portion 133b which protrudes upward from flat portion 133a and on which p-type second clad layer 134 is arranged. The height of protruding portion 133b protruding from flat portion 133a is less than the thickness of p-type first clad layer 133 in flat portion 133a. In the present embodiment, the height of protruding portion 133b of p-type first clad layer 133 protruding from flat portion 133a is less than or equal to the thickness of the periodic film of the superlattice structure of p-type first clad layer 133. A layer which is stacked uppermost of the superlattice structure of p-type first clad layer 133 is exposed to the uppermost surface of flat portion 133a. Specifically, the height of protruding portion 133b protruding from flat portion 133a is greater than 0 nm and less than 3 nm. The thickness of p-type first clad layer 133 in flat portion 133a is greater than 57 nm and less than 60 nm. Protruding portion 133b is included in ridge 180.

P-type second clad layer 134 is an example of a second conductive second clad layer arranged on the second conductive first clad layer. P-type second clad layer 134 is included in ridge 180. P-type second clad layer 134 includes Al_{z}Ga_{1-z}N (0≤z≤y). In the present embodiment, p-type second clad layer 134 is formed with a GaN layer having a thickness of 100 nm, and includes Mg or the like as a p-type dopant. The concentration of Mg or the like included as a p-type dopant in p-type first clad layer 133 may be higher than the concentration of Mg or the like included as a p-type dopant in p-type second clad layer 134. The thickness of p-type second clad layer 134 may be less than that of p-type third clad layer 135 which will be described later. In this way, it is possible to sufficiently ensure light confinement.

P-type third clad layer 135 is an example of a second conductive third clad layer arranged on the second conductive second clad layer. P-type third clad layer 135 is included in ridge 180. In the present embodiment, p-type third clad layer 135 is arranged on p-type second clad layer 134. P-type third clad layer 135 has a superlattice structure in which each of one or more AlᵥGa₁₋ᵥN layers and each of one or more Al_{w}Ga_{1-w}N layers (0≤v≤w≤1) are alternately stacked. In the present embodiment, p-type third clad layer 135 has a superlattice structure in which 100 GaN layers having a thickness of 3 nm and 100 Al₀₀₅Ga_{0.95}N layers having a thickness of 3 nm are alternately stacked, and includes Mg or the like as a p-type dopant.

P-type contact layer 140 is an example of a second conductive contact layer which is arranged on the second conductive semiconductor layer and is in ohmic contact with a second conductive side electrode. In the present embodiment, p-type contact layer 140 is a contact layer which is arranged on p-type third clad layer 135 and is in ohmic contact with p electrode 160. P-type contact layer 140 is included in ridge 180. In the present embodiment, p-type contact layer 140 is a GaN layer which includes Mg or the like as a p-type dopant and has a thickness of 50 nm.

Insulating layer 150 is an insulating member arranged between p-type semiconductor layer 130 and p electrode 160. In the present embodiment, insulating layer 150 is arranged on the side surface of ridge 180 and on the upper surface of flat portion 133a of p-type first clad layer 133, and is not arranged on the upper surface of ridge 180 (that is, the upper surface of p-type contact layer 140). Insulating layer 150 may be arranged on part of the upper surface of ridge 180. In the present embodiment, insulating layer 150 includes SiO₂. Insulating layer 150 may include a material other than SiO₂, and may include, for example, SiN, Ta₂O₅, TiO₂, or NbO₅. Insulating layer 150 may be a multilayer film in which insulating films of these materials are stacked.

As shown in FIG. 1, ridge 180 includes protruding portion 133b and p-type second clad layer 134 arranged on protruding portion 133b. In the present embodiment, ridge 180 further includes p-type third clad layer 135 and p-type contact layer 140. For example, ridge 180 is formed by using dry etching or the like and thereby removing parts of p-type first clad layer 133, p-type second clad layer 134, p-type third clad layer 135, and p-type contact layer 140 stacked on substrate 100.

P electrode 160 is an example of the second conductive side electrode which is arranged on the second conductive contact layer and is in ohmic contact with the second conductive contact layer. In the present embodiment, p electrode 160 is arranged on p-type contact layer 140 and insulating layer 150. P electrode 160 is formed of a conductive material such as Al, Pd, Ti, Pt, or Au.

N electrode 170 is an example of a first conductive side electrode arranged on the lower surface of substrate 100 (that is, one of the main surfaces of substrate 100 on which the first conductive semiconductor layer is not stacked). N electrode 170 is formed of a conductive material such as Al, Pd, Ti, Pt, or Au.

### [1-2. Manufacturing Method]

A method of manufacturing semiconductor laser element 10 according to the present embodiment will then be described with reference to FIGS. 2 to 6. FIGS. 2 to 6 are schematic cross-sectional views showing steps in the method of manufacturing semiconductor laser element 10 according to the present embodiment. FIGS. 2 to 6 show cross sections perpendicular to the longitudinal direction (that is, the direction of resonance of the laser light) of ridge 180 included in semiconductor laser element 10.

As shown in FIG. 2, on substrate 100, n-type semiconductor layer 110, active layer 120, p-type semiconductor layer 130, and p-type contact layer 140 are stacked in this order by the MOCVD or the like, and thus a semiconductor multilayer is formed.

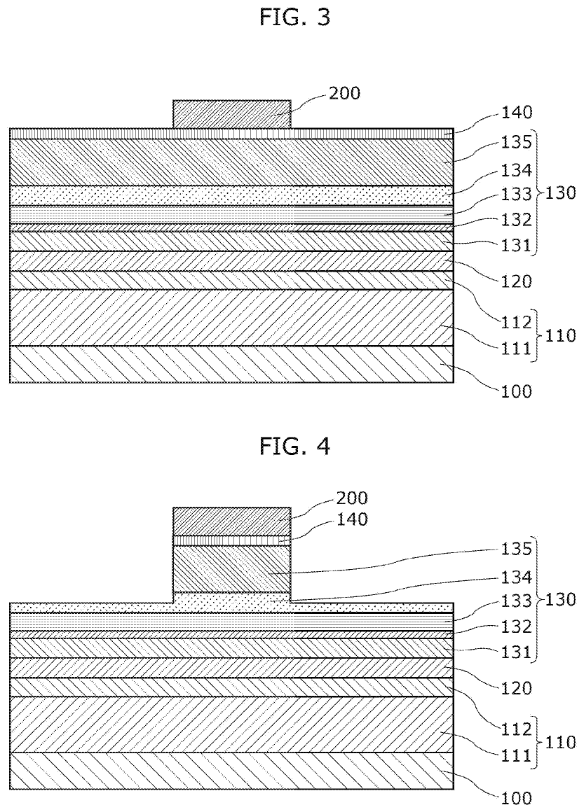

Then, as shown in FIG. 3, mask 200 is formed on the semiconductor multilayer formed in the preceding step. Specifically, a film of SiO₂ is formed by chemical vapor deposition or the like on the uppermost surface of the semiconductor multilayer (that is, the upper surface of p-type contact layer 140), and mask 200 as shown in FIG. 3 is formed by photolithography. Mask 200 is formed in a position corresponding to ridge 180 of semiconductor laser element 10.

Then, as shown in FIG. 4, the region of the semiconductor multilayer which is not covered by mask 200 is etched. Specifically, for example, a chlorine-based gas such as Cl₂ or SiCl₄ is used, and thus dry etching is performed from the upper surface of p-type contact layer 140 partway through p-type second clad layer 134. Here, for example, by film thickness monitoring using an optical interferometer or time calculation from an etching rate, the depth of the dry etching is controlled, and thus the dry etching is stopped partway through p-type second clad layer 134.

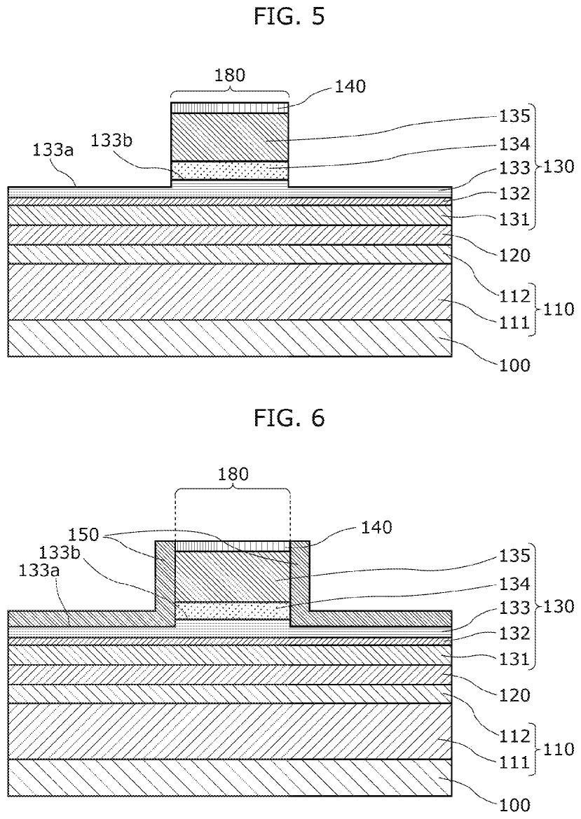

Then, as shown in FIG. 5, the region of the semiconductor multilayer which is not covered by mask 200 is further etched, and thus ridge 180 is formed. Specifically, a chlorine-based gas to which a few percent of oxygen is added is used to perform the dry etching and to thereby remove a region up to the upper surface of p-type first clad layer 133 from partway through p-type second clad layer 134. Here, since the etching rate of p-type first clad layer 133 is lower than that of p-type second clad layer 134, the etching can easily be stopped around the upper surface of p-type first clad layer 133. For example, in a bulk AlGaN layer having an average Al composition of 2.5% (that is, a layer formed of uniform AlGaN), a selectivity ratio relative to a GaN layer is about 5.5 under the etching conditions described above. On the other hand, in a superlattice layer that has a superlattice structure formed with a GaN layer and an AlGaN layer and has an average Al composition of 2.5%, a selectivity ratio relative to the GaN layer is about 8.5 under the etching conditions described above. As described above, of the layers having the same average Al composition ratio, the superlattice layer has a lower etching rate than the bulk layer. The details of the etching in the present embodiment will be described later.

As described above, the selectivity ratio between p-type first clad layer 133 and p-type second clad layer 134 is utilized, and thus it is possible to stop the etching in p-type first clad layer 133. However, it is difficult to stop the etching on the upper surface of p-type first clad layer 133 without etching p-type first clad layer 133 at all. P-type first clad layer 133 is slightly etched so that p-type second clad layer 134 in the region on which mask 200 is not formed is completely removed. In this way, as shown in FIG. 5, in p-type first clad layer 133, flat portion 133a and protruding portion 133b are formed. The height of protruding portion 133b protruding from flat portion 133a is less than the thickness of p-type first clad layer 133 in flat portion 133a. As described above, the position of the uppermost surface of the flat portion in a stacking direction can be accurately controlled to be within an upper part of the p-type first clad layer. Hence, for example, even when a plurality of semiconductor laser elements 10 are simultaneously manufactured by forming semiconductor layers and electrodes on a semiconductor wafer, the properties of semiconductor laser elements 10 can be made uniform. In the present embodiment, the height of protruding portion 133b protruding from flat portion 133a is less than or equal to the thickness of the periodic film of the superlattice structure of p-type first clad layer 133. The layer which is stacked uppermost of the superlattice structure of p-type first clad layer 133 is exposed to the uppermost surface of flat portion 133a. In this way, the position of the uppermost surface of the flat portion in the stacking direction is controlled to be less than or equal to the thickness of the periodic film of the superlattice structure, and thus the position of the uppermost surface of the flat portion of the semiconductor laser element in the stacking direction can be more accurately controlled.

Then, as shown in FIG. 6, insulating layer 150 is formed. In the present embodiment, insulating layer 150 is formed on the side surface of ridge 180 and on the upper surface of flat portion 133a of p-type first clad layer 133, for example, by chemical vapor deposition and photolithography.

Then, p electrode 160 and n electrode 170 are formed. As shown in FIG. 1, p electrode 160 is formed on p-type contact layer 140 and on insulating layer 150, and n electrode 170 is formed on the lower surface of substrate 100. P electrode 160 and n electrode 170 are formed, for example, by vacuum deposition, a lift-off method and the like.

In this way, it is possible to manufacture semiconductor laser element 10

### [1-3. Etching]

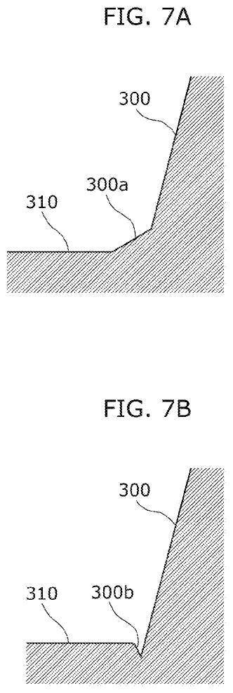

The etching performed when ridge 180 of semiconductor laser element 10 according to the present embodiment is formed will then be described in comparison with a comparative example. Dry etching in the comparative example which is not selectivity etching will first be described with reference to FIGS. 7A and 7B. FIGS. 7A and 7B are respectively schematic cross-sectional views showing first and second examples of the shape of ridge side surface 300 and etching surface 310 formed by the dry etching in the comparative example. FIGS. 7A and 7B show cross sections perpendicular to the longitudinal direction (that is, the direction of resonance of the laser light) of the ridge.

When the selectivity etching is not used, in the formation of the ridge, a boundary between ridge side surface 300 and etching surface 310 may be formed into a shape as shown in FIG. 7A or 7B depending on the conditions of the dry etching. In an example shown in FIG. 7A, in the boundary between etching surface 310 and ridge side surface 300, gentle slope portion 300a that has the shape of a gentle slope (that is, a round shape) is formed. In the vicinity of the boundary between etching surface 310 and ridge side surface 300 where gentle slope portion 300a is formed, a reaction product caused by the etching is easily deposited. This reaction product inhibits the etching to form gentle slope portion 300a.

In an example shown in FIG. 7B, in the boundary between etching surface 310 and ridge side surface 300, groove (that is, sub-trench) 300b is formed. An etching gas is transmitted along ridge side surface 300 and is sprayed to etching surface 310, and thus a local portion is excessively etched, with the result that groove 300b is formed.

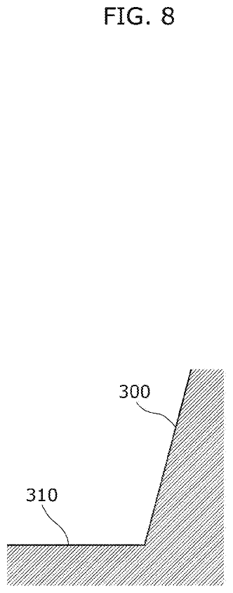

On the other hand, a case where the selectivity etching is performed as in the step of forming ridge 180 in the present embodiment will be described with reference to FIG. 8. FIG. 8 is a cross-sectional view schematically showing an example of the shape of ridge side surface 300 and etching surface 310 formed by the selectivity etching. FIG. 8 shows a cross section perpendicular to the longitudinal direction (that is, the direction of resonance of the laser light) of the ridge. As shown in FIG. 8, in the selectivity etching, a layer whose etching rate is high and a layer whose etching rate is low are stacked, and thus a tendency (that is, a tendency to form gentle slope portion 300a or groove 300b) in the comparative example described above is suppressed. Hence, the shape of ridge side surface 300 and etching surface 310 is close to the shape shown in FIG. 8. In this way, the shape of ridge 180 formed by the dry etching is simplified, and thus design using a simulation or the like is easily performed. An error between the shape of ridge 180 actually formed and a designed shape is also suppressed.

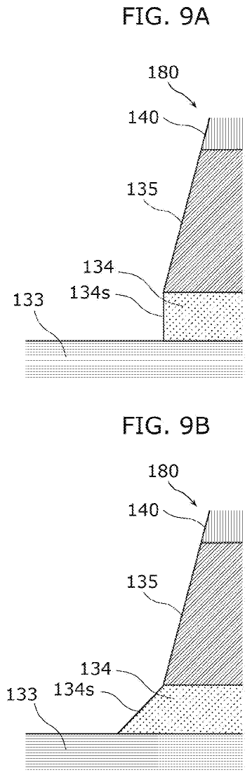

When the selectivity etching is used, the shape of the side surface of ridge 180 can be changed by a change in the etching rate. The shape of the side surface of ridge 180 when the selectivity etching is used will be described below with reference to FIGS. 9A and 9B. FIGS. 9A and 9B are respectively schematic cross-sectional views showing first and second examples of the shape of the side surface of ridge 180 in the present embodiment. FIGS. 9A and 9B show cross sections perpendicular to the longitudinal direction (that is, the direction of resonance of the laser light) of the ridge. In FIGS. 9A and 9B, flat portion 133a and protruding portion 133b of p-type first clad layer 133 are omitted.

As shown in FIGS. 9A and 9B, the inclination of side surface 134s of p-type second clad layer 134 in the side surface of ridge 180 may be changed according to the change in the etching rate caused by the selectivity etching. Depending on the conditions of the dry etching, the inclination of side surface 134s of p-type second clad layer 134 may be increased (see FIG. 9A) or decreased (see FIG. 9B).

Under the etching conditions in the present embodiment, the change in the etching rate relative to the concentration of Al is small, and thus the etching selectivity ratio of GaN to AlGaN is about 1.0 to 1.5. However, in an AlGaN layer, a superlattice structure formed with a GaN layer and an AlGaN layer is used, and thus it is possible to lower the etching rate. In other words, it is possible to increase the selectivity ratio of the GaN layer to the AlGaN layer.

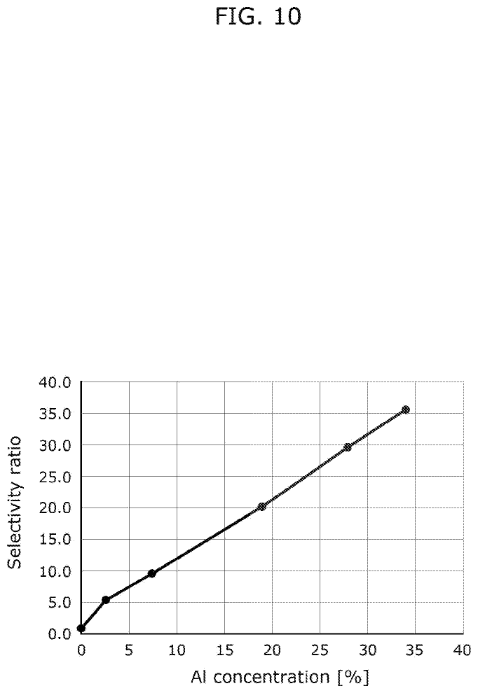

The enhancement of the selectivity ratio performed by using the superlattice structure is caused by two effects of (1) the diffusion of Al into the GaN layer in the superlattice structure of the GaN layer and the AlGaN layer and (2) a piezoelectric field applied to the GaN layer in the superlattice structure. The enhancement of the selectivity ratio performed by using the superlattice structure will be described below with reference to FIGS. 10 to 12. FIG. 10 is a graph showing the dependence of the selectivity ratio of GaN to AlGaN on the concentration of Al in AlGaN. The horizontal axis of the graph in FIG. 10 represents the concentration of Al in AlGaN, and the vertical axis represents a selectivity ratio of GaN to bulk AlGaN under etching conditions using a chlorine-based gas to which oxygen is added.

As shown in FIG. 10, when the concentration of Al is greater than or equal to about 2.5%, the selectivity ratio is linearly increased with the concentration of Al whereas when the concentration of Al is 0%, that is, when only GaN is used, the selectivity ratio does not have the linear tendency described above. The characteristic of the selectivity ratio as described above contributes to the fact that when GaN includes only a small amount of Al, the etching is inhibited by aluminum oxide formed as a by-product and thus the etching rate is lowered.

Here, when the superlattice structure of the GaN layer and the AlGaN layer is formed, Al included in the AlGaN layer of the superlattice structure is diffused into the GaN layer by heat. Hence, a trace amount of Al is also included in the GaN layer included in the superlattice structure, and thus the etching rate thereof is lowered as compared with the GaN layer which does not include Al. Therefore, in the superlattice structure of the GaN layer and the AlGaN layer, the selectivity ratio is increased.

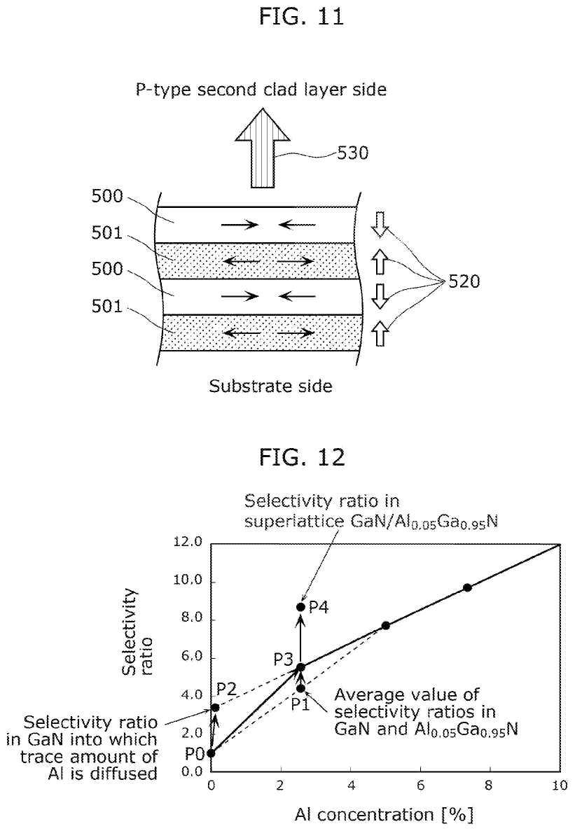

In the superlattice structure of the GaN layer and the AlGaN layer, distortion is caused by a lattice constant mismatch between the GaN layer and the AlGaN layer. By piezoelectric polarization caused by this distortion, a periodic piezoelectric field is generated. The piezoelectric field as mentioned above will be described with reference to FIG. 11. FIG. 11 is a schematic view showing the piezoelectric field applied to the superlattice structure of the GaN layer and the AlGaN layer. In FIG. 11, the direction of the piezoelectric field is indicated by arrows 520, and the direction of a bias electric field applied when the etching is performed is also indicated by arrow 530. As shown in FIG. 11, in the superlattice structure of GaN layer 500 and AlGaN layer 501, compression distortion and tensile distortion are generated in GaN layer 500 and AlGaN layer 501, respectively. In other words, stress is generated in the direction of arrows in the horizontal direction (that is, the lateral direction) shown in the layers of FIG. 11. Accordingly, the piezoelectric field in the direction indicated by arrow 520 is generated in each of the layers. As shown in FIG. 11, the direction of the piezoelectric field in GaN layer 500 of the superlattice structure is opposite to the direction of the bias electric field for the etching, and thus at least part of the bias electric field is cancelled out, with the result that the etching rate in GaN layer 500 is lowered. By contrast, although in AlGaN layer 501 of the superlattice structure, the direction of the piezoelectric field is the same as that of the bias electric field for the etching, since aluminum oxide is formed by oxygen included in the etching gas to inhibit the etching, with the result that the etching rate in AlGaN layer 501 is not enhanced. Consequently, in the superlattice structure of GaN layer 500 and AlGaN layer 501, the selectivity ratio is increased.

The selectivity ratio in the superlattice structure discussed above will be described with reference to FIG. 12. FIG. 12 is a graph showing a difference in selectivity ratio between the superlattice structure and bulk AlGaN. The graph of FIG. 12 is a graph in which an area of the graph of FIG. 10 where the concentration of Al is less than or equal to 10% is enlarged.

For example, a selectivity ratio in a superlattice structure formed with the GaN layer and the Al₀₀₅Ga_{0.95}N layer is estimated to be the average value (see point P1 in FIG. 12) of the selectivity ratio in the GaN layer and the selectivity ratio in the bulk Al₀₀₅Ga_{0.95}N layer. However, as described above, the GaN layer which does not include Al and the GaN layer into which a trace amount of Al is diffused significantly differ in selectivity ratio. As shown in FIG. 12, in the GaN layer, the selectivity ratio is 1 (see point P0 in FIG. 12) whereas in the GaN layer into which a trace amount of Al is diffused, the selectivity ratio is increased to 3 or more (see point P2 in FIG. 12). Hence, as in the GaN layer of the superlattice structure, the selectivity ratio in the superlattice structure of the GaN layer into which a trace amount of Al is diffused and the Al₀₀₅Ga_{0.95}N layer can be said to be increased to a selectivity ratio indicated by point P3 and serving as the average of the selectivity ratio at point P2 in FIG. 12 and the selectivity ratio when the concentration of Al is 5%. Furthermore, as described above, the piezoelectric field whose direction is opposite to the direction of the bias electric field for the etching is generated in the GaN layer of the superlattice structure, and thus the etching rate is lowered. Hence, the selectivity ratio in the superlattice structure of the GaN layer and the Al₀₀₅Ga_{0.95}N layer is increased to a selectivity ratio indicated by point P4 in FIG. 12. Therefore, the selectivity ratio in the superlattice structure of the GaN layer and the Al₀₀₅Ga_{0.95}N layer is significantly increased beyond the average value of the selectivity ratio in the GaN layer and the selectivity ratio in the Al₀₀₅Ga_{0.95}N layer.

As described above, the superlattice structure of the GaN layer and the AlGaN layer is used, and thus it is possible to increase the selectivity ratio even in the layer having a low average Al composition ratio. Hence, it is possible to realize an AlGaN layer (superlattice layer) having a low Al composition ratio and capable of being used as an etching stop layer.

In general, when an AlGaN layer having a high Al composition ratio is used as the etching stop layer, the AlGaN layer has high resistance, and this contributes to an increase in the drive voltage of a semiconductor laser element. However, p-type first clad layer 133 which has the superlattice structure of the GaN layer and the AlGaN layer is used as the etching stop layer, and thus a selectivity ratio equivalent to the bulk AlGaN layer can be realized in p-type first clad layer 133 having a lower average Al composition ratio. Hence, p-type first clad layer 133 having the superlattice structure is used, and thus the resistance value of p-type first clad layer 133 can be reduced as compared with a case where the bulk AlGaN layer is used as p-type first clad layer 133, with the result that it is possible to reduce the drive voltage of semiconductor laser element 10.

### [1-4. Effects and Like]

As described above, semiconductor laser element 10 according to the present embodiment includes ridge 180. Semiconductor laser element 10 includes p-type first clad layer 133 and p-type second clad layer 134 arranged on p-type first clad layer 133. P-type first clad layer 133 has a superlattice structure in which each of one or more AlₓGa₁₋ₓN layers and each of one or more Al_{y}Ga_{1-y}N layers (0≤x≤y≤1) are alternately stacked, and p-type second clad layer 134 includes Al_{z}Ga_{1-z}N (0≤z≤y). P-type first clad layer 133 includes: flat portion 133a on which p-type second clad layer 134 is not arranged; and protruding portion 133b which protrudes upward from flat portion 133a and on which p-type second clad layer 134 is arranged. Ridge 180 includes protruding portion 133b and p-type second clad layer 134 arranged on protruding portion 133b, and the height of protruding portion 133b protruding from flat portion 133a is less than the thickness of p-type first clad layer 133 in flat portion 133a.

As described above, p-type first clad layer 133 has the superlattice structure, and thus by a relatively low Al composition ratio, it is possible to increase the selectivity ratio of the etching for the GaN layer. Hence, in p-type first clad layer 133, the etching can be reliably stopped. In this way, when ridge 180 is formed by the etching, the height of protruding portion 133b formed by the etching of p-type first clad layer 133 and protruding from flat portion 133a can be reduced to the thickness of p-type first clad layer 133 in flat portion 133a or less. As described above, the position of the uppermost surface of flat portion 133a in the stacking direction can be accurately controlled to be within an upper part of p-type first clad layer 133. Hence, for example, even when a plurality of semiconductor laser elements 10 are simultaneously manufactured by forming semiconductor layers and electrodes on a semiconductor wafer, the properties of semiconductor laser elements 10 can be made uniform. More specifically, it is possible to reduce variations in the confinement of light and current in each of semiconductor laser elements 10. In an array type semiconductor laser element which includes a plurality of ridges 180, the output characteristics of ridges 180 can be made uniform. The selectivity ratio of the etching for the GaN layer in p-type first clad layer 133 is increased, and thus it is possible to reduce the formation of a gentle slope portion or a groove between the uppermost surface of the flat portion and the side surface of the protruding portion.

P-type first clad layer 133 has the superlattice structure, and thus it is possible to reduce the Al composition ratio in p-type first clad layer 133 and to increase the selectivity ratio, with the result that it is possible to reduce an increase in the resistance of p-type first clad layer 133.

In semiconductor laser element 10, a layer stacked uppermost of the superlattice structure of p-type first clad layer 133 may be exposed to the uppermost surface of flat portion 133a.

When as described above, the layer stacked uppermost of the superlattice structure of p-type first clad layer 133 is exposed to the uppermost surface of flat portion 133a, the position of the uppermost surface of flat portion 133a in the stacking direction is controlled to be within the thickness of the uppermost layer of the superlattice structure. In other words, the position of the uppermost surface of flat portion 133a of semiconductor laser element 10 in the stacking direction can be more accurately controlled. Hence, the output characteristics of the semiconductor laser element can be further stabilized.

Semiconductor laser element 10 may include p-type third clad layer 135 arranged on p-type second clad layer 134

In this way, it is possible to enhance light confinement in active layer 120.

In semiconductor laser element 10, the thickness of p-type second clad layer 134 may be less than the thickness of p-type third clad layer 135.

In this way, even when the refractive index of p-type second clad layer 134 is higher than the average refractive index of p-type first clad layer 133, it is possible to achieve sufficient light confinement in active layer 120 using p-type third clad layer 135.

In semiconductor laser element 10, p-type third clad layer 135 may have a superlattice structure in which each of one or more AlᵥGa₁₋ᵥN layers and each of one or more Al_{w}Ga_{1-w}N layers (0≤v≤w≤1) are alternately stacked.

In this way, it is possible to reduce the electrical resistance of p-type third clad layer 135, and thus it is possible to reduce the drive voltage of semiconductor laser element 10.

In semiconductor laser element 10, the height of protruding portion 133b of p-type first clad layer 133 protruding from flat portion 133a may be less than or equal to the thickness of the periodic film of the superlattice structure of p-type first clad layer 133.

When as described above, the height of the protruding portion protruding from the flat portion is less than or equal to the thickness of the periodic film of the superlattice structure of the p-type first clad layer, the position of the uppermost surface of the flat portion in the stacking direction is controlled to be less than or equal to the thickness of the periodic film of the superlattice structure. In other words, the position of the uppermost surface of the flat portion of the semiconductor laser element in the stacking direction can be more accurately controlled. Hence, the output characteristics of the semiconductor laser element can be further stabilized.

In semiconductor laser element 10, p-type first clad layer 133 may have a superlattice structure in which each of one or more AlₓGa₁₋ₓN layers and each of one or more Al_{y}Ga_{1-y}N layers (0≤x≤y≤0.5) are alternately stacked.

As described above, the Al composition ratio in p-type first clad layer 133 can be reduced to 0.5 or less, and thus it is possible to reduce the electrical resistance of p-type first clad layer 133.

In semiconductor laser element 10, p-type first clad layer 133 may have a superlattice structure in which each of one or more AlₓGa₁₋ₓN layers and each of one or more Al_{y}Ga_{1-y}N layers (0≤x≤y≤0.2) are alternately stacked.

As described above, the Al composition ratio in p-type first clad layer 133 can be reduced to 0.2 or less, and thus it is possible to further reduce the electrical resistance of p-type first clad layer 133.

In semiconductor laser element 10, p-type first clad layer 133 may have a superlattice structure in which each of one or more AlₓGa₁₋ₓN layers and each of one or more Al_{y}Ga_{1-y}N layers (0≤x≤y≤0.1) are alternately stacked.

As described above, the Al composition ratio in p-type first clad layer 133 can be reduced to 0.1 or less, and thus it is possible to further reduce the electrical resistance of p-type first clad layer 133.

### Embodiment 2

A semiconductor laser element according to Embodiment 2 will be described. The semiconductor laser element according to the present embodiment differs from semiconductor laser element 10 according to Embodiment 1 in that an oxide film is arranged between p-type semiconductor layer 130 and insulating layer 150. The semiconductor laser element according to the present embodiment will be described below with reference to FIG. 10 mainly on a configuration different from semiconductor laser element 10 according to Embodiment 1.

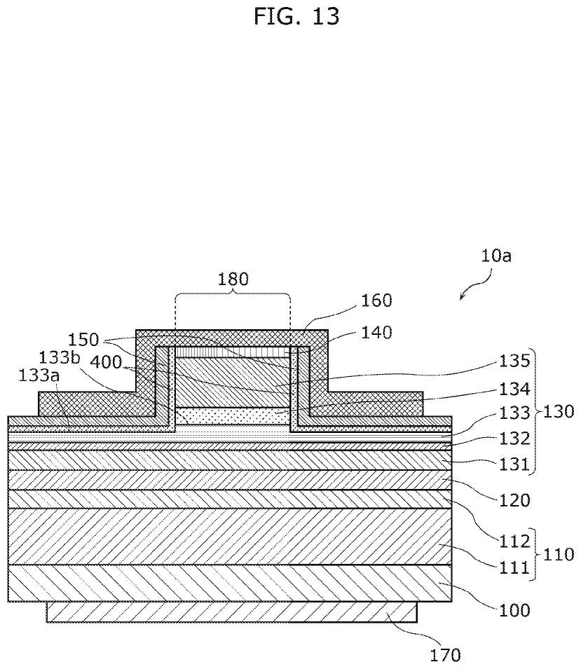

FIG. 13 is a cross-sectional view showing an overall configuration of semiconductor laser element 10a according to the present embodiment. FIG. 13 shows a cross section perpendicular to the longitudinal direction (that is, the direction of resonance of the laser light) of ridge 180 included in semiconductor laser element 10a.

As shown in FIG. 13, semiconductor laser element 10a according to the present embodiment includes, as with semiconductor laser element 10 according to Embodiment 1, substrate 100, n-type semiconductor layer 110, active layer 120, p-type semiconductor layer 130, p-type contact layer 140, insulating layer 150, p electrode 160, and n electrode 170. Semiconductor laser element 10a according to the present embodiment further includes oxide film 400.

Oxide film 400 is an oxide film which is arranged between p-type semiconductor layer 130 and insulating layer 150. More specifically, oxide film 400 is arranged between the upper surface of flat portion 133a of p-type first clad layer 133, the side surface of ridge 180, and insulating layer 150.

For example, oxide film 400 can be formed when the selectivity etching using the chlorine-based gas to which a few percent of oxygen is added is performed in the step of forming ridge 180 described in the method of manufacturing semiconductor laser element 10 according to Embodiment 1. Since oxide film 400 is formed by oxidizing a nitride semiconductor (here, GaN or AlGaN), oxide film 400 includes aluminum oxide or gallium oxide. The thickness of oxide film 400 is less than or equal to 100 nm. The thickness of oxide film 400 may be greater than or equal to 10 nm. Oxide film 400 is not limited to a film in which the nitride semiconductor is completely oxidized, and oxide film 400 may be a film in which part thereof is oxidized. For example, oxide film 400 may be a film which has a composition represented by Al_{α}Ga_{1-α}O_{β}N_{1-β} (0≤α≤1, 0<β≤1).

In semiconductor laser element 10a having the configuration as described above, the same effects as in semiconductor laser element 10 according to Embodiment 1 are achieved.

### OTHER EMBODIMENTS

Although the semiconductor laser element according to the present disclosure has been described above based on the embodiments, the present disclosure is not limited to these embodiments. Embodiments obtained by performing various variations conceived by a person skilled in the art on the embodiments or embodiments established by combining constituent elements in the different embodiments may be included in the range of one or a plurality of aspects without departing from the spirit of the present disclosure.

For example, although in the embodiments described above, the first conductive type and the second conductive type are respectively the n-type and the p-type, the first conductive type and the second conductive type may be the p-type and the n-type, respectively. Specifically, the p-type semiconductor layer may be stacked between substrate 100 and active layer 120, and the n-type semiconductor layer may be stacked above active layer 120.

Although in the embodiments described above, semiconductor laser element 10 includes n-side light guide layer 112, p-side light guide layer 131, p-type OFS layer 132, and p-type third clad layer 135, these layers are not essential constituent elements. In other words, the semiconductor laser element according to the present disclosure may omit at least one of these layers.

Although in the embodiments described above, the semiconductor laser element includes one ridge, the semiconductor laser element may include a plurality of ridges.

In the embodiments described above, p-type first clad layer 133 and p-type third clad layer 135 may have the superlattice structure of the same layers. Specifically, the AlₓGa₁₋ₓN layer and the Al_{y}Ga_{1-y}N layer included in p-type first clad layer 133 may respectively have the same compositions of the AlᵥGa₁₋ᵥN layer and the Al_{w}Ga_{1-w} layer included in p-type third clad layer 135. In other words, for x, y, v, and w in the Al composition ratio, x=v and y=w may be established.

### INDUSTRIAL APPLICABILITY

The semiconductor laser element according to the present disclosure can be utilized as a low drive voltage semiconductor laser element which has stable output characteristics and reduces an increase in resistance, such as a light source for a processing laser device.

1. A semiconductor laser element including a ridge, the semiconductor laser element comprising:
a p-type first clad layer; and
a p-type second clad layer arranged on the p-type first clad layer,
wherein the p-type first clad layer has a superlattice structure in which each of one or more AlₓGa₁₋ₓN layers and each of one or more Al_{y}Ga_{1-y}N layers are alternately stacked, where 0≤x≤y≤1,
the p-type second clad layer includes Al_{z}Ga_{1-z}N, where 0≤z≤y,
the p-type first clad layer includes:
a flat portion on which the p-type second clad layer is not arranged; and
a protruding portion which protrudes upward from the flat portion and on which the p-type second clad layer is arranged,
the ridge includes the protruding portion and the p-type second clad layer arranged on the protruding portion, and
a height of the protruding portion protruding from the flat portion is less than a thickness of the p-type first clad layer in the flat portion.

2. The semiconductor laser element according to claim 1,
wherein a layer stacked uppermost of the superlattice structure of the p-type first clad layer is exposed to an uppermost surface of the flat portion.

3. The semiconductor laser element according to claim 1, comprising:
a p-type third clad layer arranged on the p-type second clad layer.

4. The semiconductor laser element according to claim 3,
wherein a thickness of the p-type second clad layer is less than a thickness of the p-type third clad layer.

5. The semiconductor laser element according to claim 3,
wherein the p-type third clad layer has a superlattice structure in which each of one or more Al_{w}Ga_{1-w}N layers and each of one or more Al_{w}Ga_{1-w}N layers are alternately stacked, where 0≤v≤w≤1.

6. The semiconductor laser element according to claim 1,
wherein the height of the protruding portion of the p-type first clad layer is less than or equal to a thickness of a periodic film of the superlattice structure of the p-type first clad layer.

7. The semiconductor laser element according to claim 1,
wherein the p-type first clad layer has a superlattice structure in which each of one or more AlₓGa₁₋ₓN layers and each of one or more Al_{y}Ga_{1-y}N layers are alternately stacked, where 0≤x≤y≤0.5.

8. The semiconductor laser element according to claim 1,
wherein the p-type first clad layer has a superlattice structure in which each of one or more AlₓGa₁₋ₓN layers and each of one or more Al_{y}Ga_{1-y}N layers are alternately stacked, where 0≤x≤y≤0.2.

9. The semiconductor laser element according to claim 1,
wherein the p-type first clad layer has a superlattice structure in which each of one or more AlₓGa₁₋ₓN layers and each of one or more Al_{y}Ga_{1-y}N layers are alternately stacked, where 0≤x≤y≤0.1.
